(19) United States
(12) Patent Application Publication
(10) Pub. No.: US 2025/0047056 A1
(43) Pub. Date: Feb. 6, 2025

(54) OPTICAL MODULATOR INTEGRATED LASER, OPTICAL MODULATOR, AND OPTICAL SEMICONDUCTOR DEVICE

(71) Applicant: Sumitomo Electric Device Innovations, Inc., Yokohama-shi (JP)

(72) Inventor: Hiromitsu KAWAMURA, Yokohama-shi (JP)

(73) Assignee: Sumitomo Electric Device Innovations, Inc., Yokohama-shi (JP)

(21) Appl. No.: 18/787,029

(22) Filed: Jul. 29, 2024

(30) Foreign Application Priority Data
Jul. 31, 2023 (JP) 2023-124837

(51) Int. Cl. H01S 5/00; H01S 5/042

(52) U.S. Cl. CPC H01S 5/0085; H01S 5/04256

(57) ABSTRACT

An optical modulator integrated laser includes a substrate, a laser portion provided on the substrate and outputting laser light, an optical modulation portion provided on the substrate and modulating the laser light, and a first terminating portion provided on the substrate and including a first resistive film. The optical modulation portion includes a modulation electrode that is supplied with a modulation signal, a signal pad connected to the modulation electrode and for being connected to a first wire for inputting the modulation signal to the optical modulation portion, and a first pad for being connected to a second wire having a ground potential. The signal pad and one end of the first resistive film are connected to each other. The other end of the first resistive film and the first pad are connected to each other.

### CROSS-REFERENCE TO RELATED APPLICATION

The present application is based upon and claims the benefit of the priority from Japanese patent application No. 2023-124837 filed on Jul. 31, 2023, the entire contents of which are incorporated herein by reference.

### TECHNICAL FIELD

The present disclosure relates to an optical modulator integrated laser, an optical modulator, and an optical semiconductor device.

### BACKGROUND

Japanese Unexamined Patent Publication No. 2001-308130 discloses techniques for a high-frequency circuit and a module and a communicator on which the high-frequency circuit is mounted. The high-frequency circuit has a configuration in which a signal line for transmitting a high-frequency signal and an element having capacitance are connected by a first bonding wire and the element having capacitance and a terminating resistor for impedance matching are connected by a second bonding wire. In the high-frequency circuit, a magnitude of characteristic impedance of a transmission line constituted by the first bonding wire, the second bonding wire, and the element having capacitance is larger than a magnitude of characteristic impedance on an input side of the high-frequency signal. In the high-frequency circuit, a magnitude of inductance of the first bonding wire is smaller than a magnitude of inductance of the second bonding wire.

### SUMMARY

An optical modulator integrated laser according to an embodiment of the present disclosure includes a substrate, a laser portion provided on the substrate and outputting laser light, an optical modulation portion provided on the substrate and modulating the laser light, and a first terminating portion provided on the substrate and including a first resistive film. The optical modulation portion includes a modulation electrode that is supplied with a modulation signal, a signal pad connected to the modulation electrode and for being connected to a first wire for inputting the modulation signal to the optical modulation portion, and a first pad for being connected to a second wire having aground potential. The signal pad and one end of the first resistive film are connected to each other. Another end of the first resistive film and the first pad are connected to each other.

### BRIEF DESCRIPTION OF THE DRAWINGS

FIG. 1 is a plan view illustrating a small optical transmission device according to a first embodiment of the present disclosure.

FIG. 2 is a circuit diagram illustrating a circuit included in the small optical transmission device according to the first embodiment.

FIG. 3 is a perspective view illustrating an optical semiconductor device that is provided in the small optical transmission device according to the first embodiment.

FIG. 4 is a plan view illustrating the optical semiconductor device according to the first embodiment.

FIG. 5 is an enlarged view illustrating pads and a terminating portion according to the first embodiment.

FIG. 6 is a sectional view taken along line VI-VI in FIG. 4.

FIG. 7 is a sectional view illustrating some steps for manufacturing the optical semiconductor device illustrated in FIG. 4.

FIG. 8 is a perspective view illustrating an optical semiconductor device according to a first modified example.

FIG. 9 is a plan view illustrating the optical semiconductor device according to the first modified example.

FIG. 10 is a perspective view illustrating an optical semiconductor device according to a second embodiment.

FIG. 11 is a plan view illustrating the optical semiconductor device according to the second embodiment.

FIG. 12 is a plan view illustrating an optical semiconductor device according to a comparative example.

### DETAILED DESCRIPTION

With an increase in speed and capacity of optical communication, there is need for an increase in frequency band of an optical modulator of an optical semiconductor device. However, when a modulation signal has a high frequency such as 100 GHz or higher, electrical reflection of the modulation signal is likely to increase. When reflection of a modulation signal increases, a loss of the modulation signal increases. Accordingly, for example, the modulation signal may not be likely to be satisfactorily transmitted to the optical modulator.

An objective of the present disclosure is to provide an optical modulator integrated laser, an optical modulator, and an optical semiconductor device that can decrease a loss of a modulation signal due to reflection.

### Embodiments of Present Disclosure

Details of embodiments of the present disclosure will be first mentioned below.

(1) An optical modulator integrated laser according to an embodiment of the present disclosure includes a substrate, a laser portion provided on the substrate and outputting laser light, an optical modulation portion provided on the substrate and modulating the laser light, and a first terminating portion provided on the substrate and including a first resistive film. The optical modulation portion includes a modulation electrode that is supplied with a modulation signal, a signal pad connected to the modulation electrode and for being connected to a first wire for inputting the modulation signal to the optical modulation portion, and a first pad for being connected to a second wire having a ground potential. The signal pad and one end of the first resistive film are connected to each other. Another end of the first resistive film and the first pad are connected to each other. An optical modulator according to an embodiment of the present disclosure includes a substrate, an optical modulation portion provided on the substrate and modulating laser light, and a first terminating portion provided on the substrate and including a first resistive film. The optical modulation portion includes a modulation electrode that is supplied with a modulation signal, a signal pad connected to the modulation electrode and for being connected to a first wire for inputting the modulation signal to the optical modulation portion, and a first pad for being connected to a second wire having a ground potential. The signal pad and one end of the first resistive film are connected to each other. Another end of the first resistive film and the first pad are connected to each other.

In the optical modulator integrated laser and the optical modulator according to (1), the signal pad, the first pad, and the first resistive film included in the first terminating portion are provided on the same substrate. Accordingly, the length of the conductive path between the one end of the first resistive film and the connection point between the first wire and the signal pad can be extremely decreased. As a result, it is possible to decrease electrical reflection of a modulation signal from the one end of the first resistive film of the first terminating portion. Accordingly, it is possible to obtain an optical modulator integrated laser and an optical modulator that can decrease a loss of the modulation signal due to reflection.

(2) In the optical modulator integrated laser and the optical modulator according to (1), a length of a conductive path between the one end of the first resistive film and a connection point between the first wire and the signal pad may be less than ¼ of a wavelength of the modulation signal. According to the inventor's knowledge, even if a modulation signal has a high frequency such as 100 GHz or higher, it is less likely to increase electrical reflection of the modulation signal from one end of the first resistive film of the first terminating portion when the length of the conductive path between the one end of the first resistive film and the connection point between the first wire and the signal pad is less than ¼ of a wavelength of the modulation signal. Accordingly, it is possible to effectively decrease a loss of the modulation signal due to reflection.

(3) The optical modulator integrated laser and the optical modulator according to (1) or (2) may further include a second terminating portion provided on the substrate and including a second resistive film. The optical modulation portion may further include a second pad provided on a side opposite to the first pad with respect to the signal pad and for being connected to a third wire having the ground potential. The signal pad and one end of the second resistive film may be connected to each other. Another end of the second resistive film and the second pad may be connected to each other. In the optical modulator integrated laser and the optical modulator according to (3), the third wire connected to the second pad has the ground potential. Accordingly, the modulation signal passing along the first wire is interposed between the ground potentials. As a result, it is possible to further decrease mismatching in input impedance and to further decrease the loss of the modulation signal due to mismatching in impedance. The signal pad, the second pad, and the second resistive film that is included in the second terminating portion are provided on the same substrate. Accordingly, the length of the conductive path between the one end of the second resistive film and the connection point between the first wire and the signal pad can be extremely decreased. As a result, it is possible to decrease electrical reflection of a modulation signal from the one end of the second resistive film of the second terminating portion. Accordingly, it is possible to obtain an optical modulator integrated laser and an optical modulator that can further decrease the loss of the modulation signal due to reflection.

(4) In the optical modulator integrated laser and the optical modulator according to (3), a length of a conductive path between the one end of the second resistive film and a connection point between the first wire and the signal pad may be less than ¼ of the wavelength of the modulation signal. Accordingly, similarly to the optical modulator integrated laser and the optical modulator according to (2), it is possible to decrease the loss of the modulation signal due to reflection at the one end of the second resistive film.

(5) The optical modulator according to any one of (1) to (4) may further include a laser portion provided on the substrate and outputting the laser light. Accordingly, the laser portion and the optical modulation portion can be monolithically provided on the same substrate. As a result, it is possible to decrease a size of an optical transmission device.

(6) An optical semiconductor device according to an embodiment of the present disclosure includes the optical modulator according to (1) or (2) and a transmission line transmitting the modulation signal. The transmission line includes a signal line transmitting the modulation signal and a first ground potential line having the ground potential and provided side by side with the signal line. The signal pad and the signal line are connected to each other via the first wire. The first pad and the first ground potential line are connected to each other via the second wire.

In the optical semiconductor device according to (6), the first pad is connected to the ground potential line via the second wire. Accordingly, the second wire having the ground potential can be provided on the optical modulator. The signal line is connected to the first wire. The ground potential line is connected to the second wire. Accordingly, the first wire and the second wire are arranged side by side. As a result, the modulation signal propagates side by side with the ground potential even after the modulation signal has left the signal line. Accordingly, it is possible to decrease mismatching in impedance between the signal line and the first wire. As a result, it is possible to decrease the loss of the modulation signal due to mismatching in impedance of the modulation signal.

(7) The optical semiconductor device according to claim (6) may further include a ground pattern provided on a side opposite to the transmission line with respect to the optical modulation portion. The ground pattern and the first pad may be connected to each other via a fourth wire. With the fourth wire, it is possible to enhance precision of the ground potential of the first pad and to more easily decrease the mismatching in impedance between the signal line and the first wire. Accordingly, it is possible to further decrease the loss of the modulation signal due to the mismatching in impedance.

(8) An optical semiconductor device according to an embodiment of the present disclosure includes the optical modulator according to (3) or (4) and a transmission line transmitting the modulation signal. The transmission line includes a signal line transmitting the modulation signal and a first ground potential line and a second ground potential line having the ground potential and provided side by side with the signal line. The signal pad and the signal line are connected to each other via the first wire. The first pad and the first ground potential line are connected to each other via the second wire. The second pad and the second ground potential line are connected to each other via the third wire. The third wire is provided on a side opposite to the second wire with respect to the first wire.

In the optical semiconductor device according to (8), since the second pad and the ground potential line are connected to each other via the third wire, the third wire has the ground potential. Accordingly, the first wire provided along with the second wire and the third wire is interposed between the ground potentials. As a result, the modulation signal passing along the first wire propagates while being interposed between the ground potentials. Accordingly, it is possible to more easily decrease the mismatching in impedance between the signal line and the first wire. As a result, it is possible to further decrease the loss of the modulation signal due to the mismatching in impedance.

(9) The optical semiconductor device according to (8) may further include a ground pattern provided on a side opposite to the transmission line with respect to the optical modulation portion. The ground pattern and the first pad may be connected to each other via a fourth wire. The ground pattern and the second pad may be connected to each other via a fifth wire. With the fourth wire and the fifth wire, it is possible to enhance precision of the ground potential of the first pad and the second pad and to further decrease the mismatching in impedance between the signal line and the first wire. Accordingly, it is possible to further decrease the loss of the modulation signal due to the mismatching in impedance.

(10) An optical modulator according to an embodiment of the present disclosure includes a substrate, an optical modulation portion provided on the substrate, and modulating laser light, the optical modulation portion including a modulation electrode that is supplied with a modulation signal, and a terminating portion provided on the substrate and connected to the modulation electrode and a conductor having a ground potential, the terminating portion including a resistive film. Since the optical modulation portion and the terminating portion including a resistive film are provided on the same substrate, it is possible to decrease the distance between the modulation electrode of the optical modulation portion and the terminating portion. Accordingly, it is possible to decrease electrical reflection of a modulation signal from the resistive film of the terminating portion. As a result, it is possible to obtain an optical modulator that can further decrease the loss of the modulation signal due to reflection.

### Details of Embodiments of Present Disclosure

Specific examples of an optical modulator integrated laser, an optical modulator, and an optical semiconductor device according to the present disclosure will be described below with reference to the accompanying drawings. The present disclosure is not limited to such examples, is defined by the appended claims, and is intended to include all modifications within meanings and scopes equivalent to the claims. In the following description, the same elements will be referred to by the same reference signs, and repeated description thereof will be omitted.

### First Embodiment

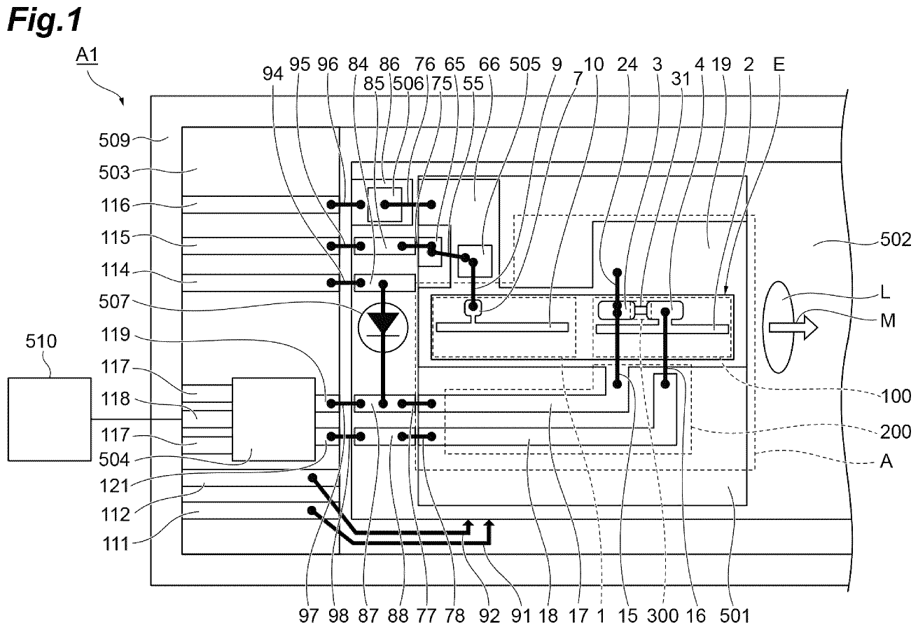

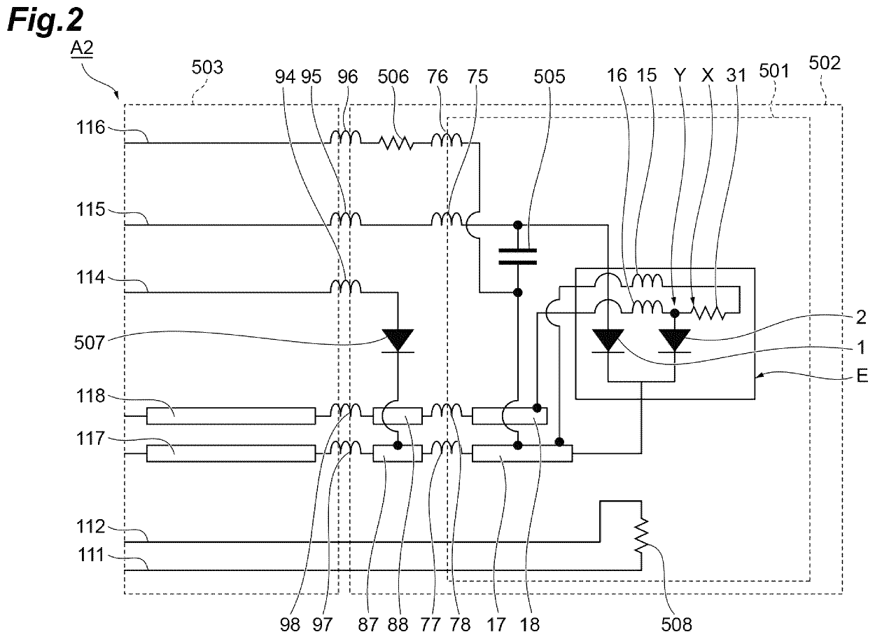

FIG. 1 is a plan view illustrating a small optical transmission device A1 according to a first embodiment of the present disclosure. FIG. 2 is a circuit diagram illustrating a circuit A2 included in the small optical transmission device A1. A configuration of the small optical transmission device A1 will be described below with reference to FIGS. 1 and 2.

As illustrated in FIG. 1, the small optical transmission device A1 includes a package 509, a substrate 501 (a chip-on-carrier), a substrate 502 (a mount carrier), and a substrate 503. The package 509 accommodates the substrate 501, the substrate 502, and the substrate 503. The substrate 502 is disposed along with the substrate 503. The substrate 501 is disposed on the substrate 502. A material of the substrate 501 and the substrate 502 is, for example, an insulator such as ceramic.

Wiring patterns 111, 112, 114, 115, and 116, ground potential lines 117 and 119, signal lines 118 and 121, and a driver IC 504 are formed on the substrate 503. The wiring patterns 111, 112, 114, 115, and 116, the ground potential line 117, and the signal line 118 extend from one side wall of the package 509 to the substrate 502 and are connected to a circuit outside of the small optical transmission device A1 via terminals which are not illustrated. A material of the wiring patterns 111, 112, 114, 115, and 116, the ground potential lines 117 and 119, and the signal lines 118 and 121 are, for example, a metal. The wiring patterns 111, 112, 114, 115, and 116, the ground potential lines 117 and 119, and the signal lines 118 and 121 are formed on an insulator, for example, through vapor deposition and then lifting-off, sputtering, or the like. The signal line 118 transmits a high-frequency modulation signal input from a circuit 510 outside of the small optical transmission device A1. The ground potential line 117 has a ground potential (a reference potential) input from the outside of the small optical transmission device A1. The signal line 118 and the ground potential line 117 constitute a transmission line. The ground potential line 119 and the signal line 121 also constitute a transmission line.

Input terminals of the driver IC 504 are connected to the ground potential line 117 and the signal line 118. Output terminals of the driver IC 504 are connected to the ground potential line 119 and the signal line 121. The driver IC 504 amplifies a modulation signal from the signal line 118 and outputs the amplified modulation signal to the signal line 121.

Description will be continued with reference to FIG. 2 along with FIG. 1. Wiring patterns 84, 85, and 86, a ground potential line 87, a signal line 88, a thermistor 506, a monitor photodiode 507, and a lens L are provided on the substrate 502. The wiring pattern 86 is connected to the wiring pattern 116 via a wire 96. The wiring pattern 85 is connected to the wiring pattern 115 via a wire 95. The wiring pattern 84 is connected to the wiring pattern 114 via a wire 94. The ground potential line 87 is connected to the ground potential line 119 via a wire 97. The signal line 88 is connected to the signal line 121 via a wire 98. A material of the wiring patterns 84, 85, and 86, the ground potential line 87, and the signal line 88 is, for example, a metal.

The thermistor 506 is provided on the wiring pattern 86. The thermistor 506 indicates a resistance value based on the temperature. The resistance value is detected by a circuit outside of the small optical transmission device A1 via the wiring pattern 86, the wire 96, and the wiring pattern 116.

The monitor photodiode 507 is connected between the wiring pattern 84 and the ground potential line 87. In order to make an average intensity of emission light M constant, the monitor photodiode 507 detects backlight emitted from an optical modulator integrated semiconductor laser E (which will be described later) of an optical semiconductor device A. The monitor photodiode 507 outputs an electrical signal corresponding to the intensity of the backlight to a circuit outside of the small optical transmission device A1 via the wiring pattern 84, the wire 94, and the wiring pattern 114. The lens L is optically coupled to a light emitting end of the optical semiconductor device A and collimates the emission light M emitted from the optical modulator integrated semiconductor laser E.

A temperature control element (TEC) 508 (illustrated in only FIG. 2) is provided in the rear of the substrate 502. One electrode of the TEC 508 is connected to the wiring pattern 111 via a wire 91. The other electrode of the TEC 508 is connected to the wiring pattern 112 via a wire 92. Electric power for driving the TEC 508 is input from a circuit outside of the small optical transmission device A1 via the wiring pattern 111 and the wiring pattern 112. The circuit outside of the small optical transmission device A1 controls the magnitude of electric power for driving the TEC 508 on the basis of the ambient temperature of the optical semiconductor device A (that is, the resistance value of the thermistor 506). Accordingly, the temperature of the optical modulator integrated semiconductor laser E is maintained at a predetermined temperature, and the wavelength of the emission light M emitted from the optical semiconductor device A is maintained at a predetermined wavelength.

A ground potential line 66, a wiring pattern 65, a bypass capacitor 505, and an optical semiconductor device A are provided on the substrate 501. One end of the ground potential line 66 is connected to a ground terminal of the thermistor 506 via a wire 76, and the other end of the ground potential line 66 is connected to a ground pattern 19 (which will be described later). The material of the ground potential line 66 is, for example, a metal. The ground potential line 66 has a ground potential.

The bypass capacitor 505 is provided on the ground potential line 66. A lower electrode of the bypass capacitor 505 is connected to the ground potential line 66. An upper electrode of the bypass capacitor 505 is connected to the wiring pattern 65 via a wire 55. The material of the wiring pattern 65 is, for example, a metal.

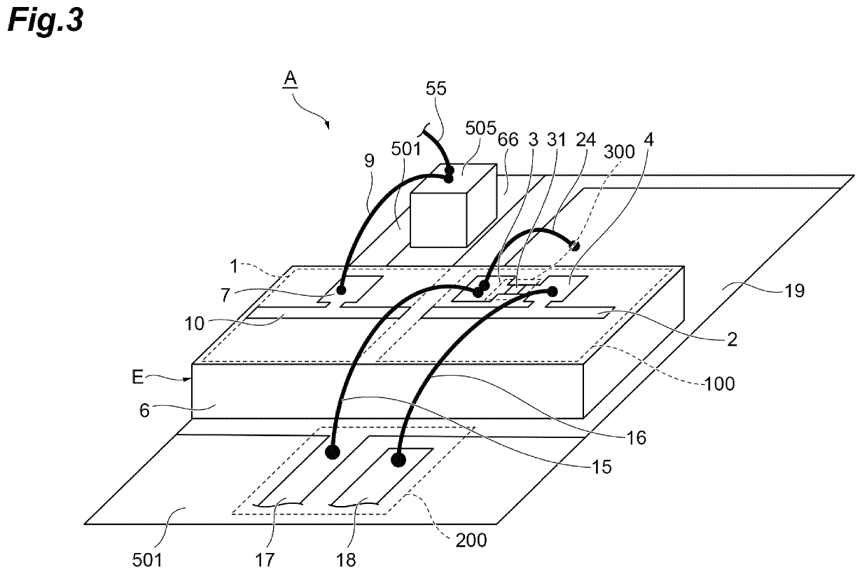

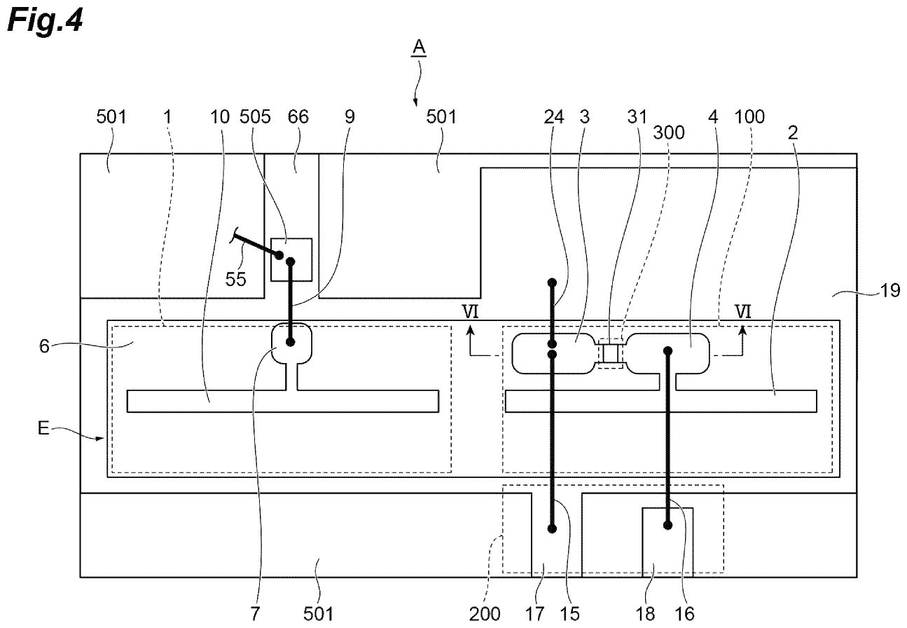

FIG. 3 is a perspective view illustrating an optical semiconductor device A that is provided in the small optical transmission device A1. FIG. 4 is a plan view illustrating the optical semiconductor device A. As illustrated in FIGS. 3 and 4, the optical semiconductor device A includes an optical modulator integrated semiconductor laser E, a ground pattern 19, and a transmission line 200. The ground pattern 19 is provided on the substrate 501. The material of the ground pattern 19 is, for example, a metal. The ground pattern 19 has the ground potential.

The transmission line 200 includes a ground potential line 17 (a first ground potential line) and a signal line 18. The ground potential line 17 is provided side by side with the signal line 18 in a direction crossing an extending direction of the ground potential line 17. The material of the ground potential line 17 and the signal line 18 is, for example, a metal. As illustrated in FIG. 1, one end of the ground potential line 17 is connected to the ground potential line 87 via a wire 77. The ground potential line 17 has the ground potential. As illustrated in FIG. 1, one end of the signal line 18 is connected to the signal line 88 via the wire 78. The signal line 18 transmits an amplified modulation signal.

The optical modulator integrated semiconductor laser E according to this embodiment is an example of an optical modulator according to the present disclosure. The optical modulator integrated semiconductor laser E is provided on the ground pattern 19 and includes a substrate 6, a laser portion 1, an optical modulation portion 100, and a terminating portion 300 (a first terminating portion). The substrate 6 is formed in a rectangular shape. The laser portion 1 is disposed on the substrate 6 on the side of the substrate 503 with respect to the optical modulation portion 100. The laser portion 1 is interposed between the transmission line 200 and the ground potential line 66 as illustrated in FIG. 1. The laser portion 1 includes an active area and generates laser light with a light intensity which is constant with time when a current is supplied to the active area. The laser portion 1 includes a drive electrode 10 and a pad 7 on a surface thereof. The drive electrode 10 extends in a laser resonance direction (a direction in which the laser portion 1 and the optical modulation portion 100 are arranged) and supplies a current to the active area. The pad 7 is disposed in parallel to a direction crossing the extending direction of the drive electrode 10 with respect to the drive electrode 10 and is connected to the drive electrode 10. The pad 7 is connected to the upper electrode of the bypass capacitor 505 via a wire 9. Accordingly, a drive current is supplied to the drive electrode 10 from the outside of the small optical transmission device A1 via the wiring pattern 115, the wiring pattern 85, the wiring pattern 65, the upper electrode of the bypass capacitor 505, and the pad 7.

The optical modulation portion 100 is provided on a side of the lens L with respect to the laser portion 1. The optical modulation portion 100 modulates laser light output from the laser portion 1 and outputs the modulated emission light M. The backlight is laser light which is output from the laser portion 1 without passing through the optical modulation portion 100. The laser portion 1 and the optical modulation portion 100 are monolithically formed on the substrate 6. The optical modulation portion 100 includes a modulation electrode 2, a pad 3 (a first pad), and a pad 4 (a signal pad). The optical modulation portion 100 includes a modulation area and modulates the laser light by transmitting or cutting off the laser light when a current is supplied to the modulation area. The modulation electrode 2 supplies a modulation current (a modulation signal) to the modulation area. Accordingly, in the modulation area, the laser light is transmitted or cut off on the basis of the input modulation signal. The modulation electrode 2 extends in the same direction as a propagating direction of the laser light in a plan view. On the top surface of the optical modulator integrated semiconductor laser E, the modulation electrode 2 is provided substantially at the center in a direction perpendicular to the propagating direction of the laser light.

The pad 3 and the pad 4 are provided on a side opposite to the transmission line 200 with respect to the modulation electrode 2. The pad 4 is provided at the center in the propagating direction of the laser light in the optical modulation portion 100. The pad 4 is connected to the modulation electrode 2 and is connected to a wire 16 (a first wire) for inputting the modulation signal to the optical modulation portion 100. The pad 3 is provided side by side with the pad 4 along the length direction of the modulation electrode 2 and is provided on a side of the laser portion 1 with respect to the pad 4. The pad 3 is connected to a wire 15 (a second wire) having the ground potential. The pad 3 is connected to the ground pattern 19 via a wire 24 (a fourth wire). The pad 3 and the pad 4 are formed in a film shape and have a substantially rectangular shape in a plan view. The material of the pad 3 and the pad 4 is a metal, for example, gold (Au). The thickness of the pad 3 and the pad 4 is, for example, equal to or greater than 3 μm and equal to or less than 10 μm.

The other end of the ground potential line 17 is connected to the ground pattern 19 and is connected to the pad 3 via a wire 15. The other end of the signal line 18 is connected to the pad 4 via the wire 16. The wire 15 is provided side by side with the wire 16. As illustrated in FIG. 4, for example, the wire 15 and the wire 16 are provided in parallel with each other in a plan view. The wire 15 and the wire 16 are, for example, bonding wires formed of Au. A sectional diameter of the wire 15 and the wire 16 is, for example, 25 μm. A gap between the wire 15 and the wire 16 is, for example, several tens of μm.

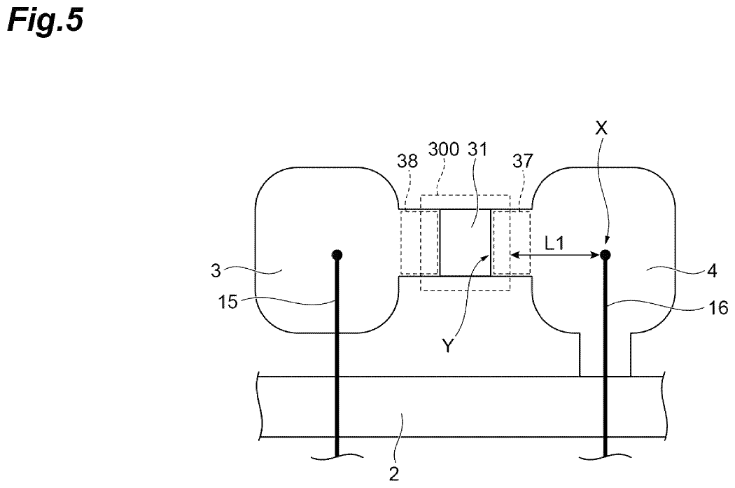

The terminating portion 300 is provided between the pad 3 and the pad 4. The terminating portion 300 includes a resistive film 31 (a first resistive film) and decreases reflection of a modulation signal. FIG. 5 is an enlarged view illustrating the pads 3 and 4 and the terminating portion 300 according to the first embodiment. The pad 4 and one end Y of the resistive film 31 are connected to each other via a wiring pattern 37. The other end of the resistive film 31 and the pad 3 are connected to each other via a wiring pattern 38. A length of a conductive path (an electrical length) L1 between a connection point X between the wire 16 and the pad 4 and the one end Y of the resistive film 31 is less than ¼, less than ⅛, less than 1/10, or less than 1/12 of a wavelength of a modulation signal and equal to or greater than 1/1000 of the wavelength. In a specific example, when the wavelength of the modulation signal is, for example, 1200 μm, L1 is less than 300 μm, less than 150 μm, less than 120 μm, or less than 100 μm and equal to or greater than 1 μm. The resistive film 31 has a rectangular shape. The material of the resistive film 31 is, for example, a metal such as nickel chromium (NiCr), titanium tungsten (TiW), tantalum nitride (TaN), or platinum (Pt). The thickness of the resistive film 31 is, for example, equal to or greater than 100 nm and equal to or less than 300 nm. The resistive film 31 is formed as a thin-film resistance pattern which is formed through vapor deposition and then lifting-off, sputtering, or the like. When an impedance value of a light absorbing layer is, for example, 90Ω, a value of terminating impedance is 50Ω by setting the resistance value of the resistive film 31 to, for example, 110Ω. The value of terminating impedance is often set to 50Ω, or may be different from 50Ω due to addition of a capacitor or an inductor or adjustment of a resistance value.

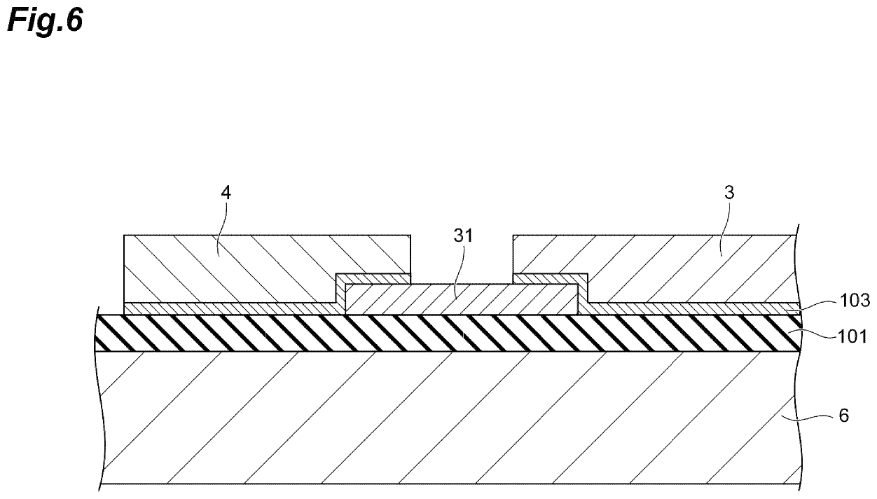

FIG. 6 is a sectional view taken along line VI-VI in FIG. 4. The optical modulation portion 100 includes a passivation film 101 and a seed layer 103 (a SEED layer) on the substrate 6. The substrate 6 is provided on the ground pattern 19 in contact with the ground pattern 19. The substrate 6 is formed of, for example, SI-InP, n-InP, or a dielectric. The passivation film 101 is provided on the substrate 6. The material of the passivation film 101 is, for example, an insulator such as SiO₂ or SiN. The thickness of the passivation film 101 is, for example, equal to or greater than 300 nm and equal to or less than 500 nm. The resistive film 31 is provided on the passivation film 101. The pad 3 and the pad 4 are provided on the passivation film 101 and include a part provided on the resistive film 31 and a part provided in an area without the resistive film 31. The seed layer 103 is provided between the passivation film 101 and both the pad 3 and the pad 4 and between the resistive film 31 and both the pad 3 and the pad 4. The material of the seed layer 103 is, for example, gold (Au). The thickness of the seed layer 103 is, for example, equal to or greater than 100 nm and equal to or less than 200 nm. The pad 3 and the pad 4 are not in contact with each other, and the resistive film 31 includes a part exposed from both the pad 3 and the pad 4.

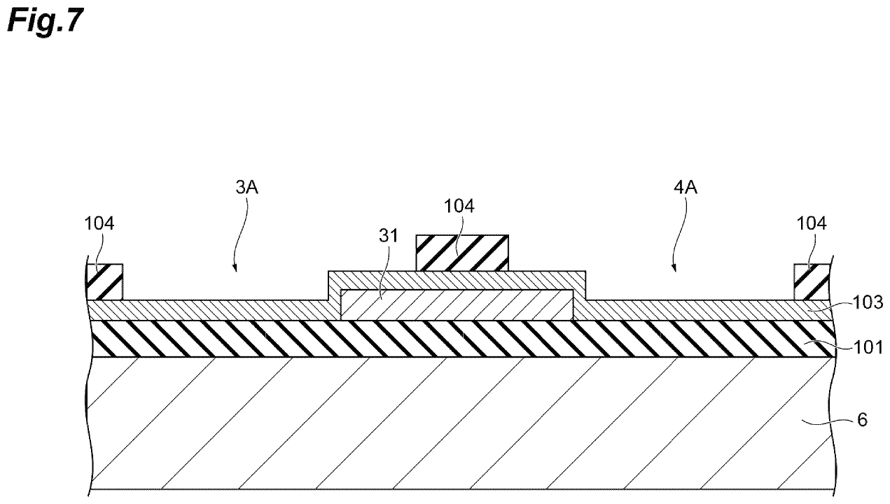

FIG. 7 is a sectional view illustrating some steps for manufacturing the optical semiconductor device A illustrated in FIG. 4. Some steps for manufacturing the optical semiconductor device A will be described below. For the optical modulation portion 100, first, a substrate 6 is prepared. Then, a passivation film 101 is formed on the substrate 6. Thereafter, a resist mask which is not illustrated is formed on the surface of the passivation film 101 through photolithography, and a resistive film 31 is formed on the passivation film 101. Then, a seed layer 103 is formed on the surfaces of the resistive film 31 and the passivation film 101. Thereafter, a resist mask 104 in which an opening 3A and an opening 4A are provided is formed on the surface of the seed layer 103 through photolithography. Subsequently, by performing gold plating on the opening 3A and the opening 4A, the pad 3 is formed in the opening 3A and the pad 4 is formed in the opening 4A. Finally, the resist mask 104 is removed from the optical modulation portion 100, and the seed layer 103 is removed using the pad 3 and the pad 4 as a mask. Accordingly, the pad 3, the terminating portion 300, and the pad 4 in FIG. 6 are formed.

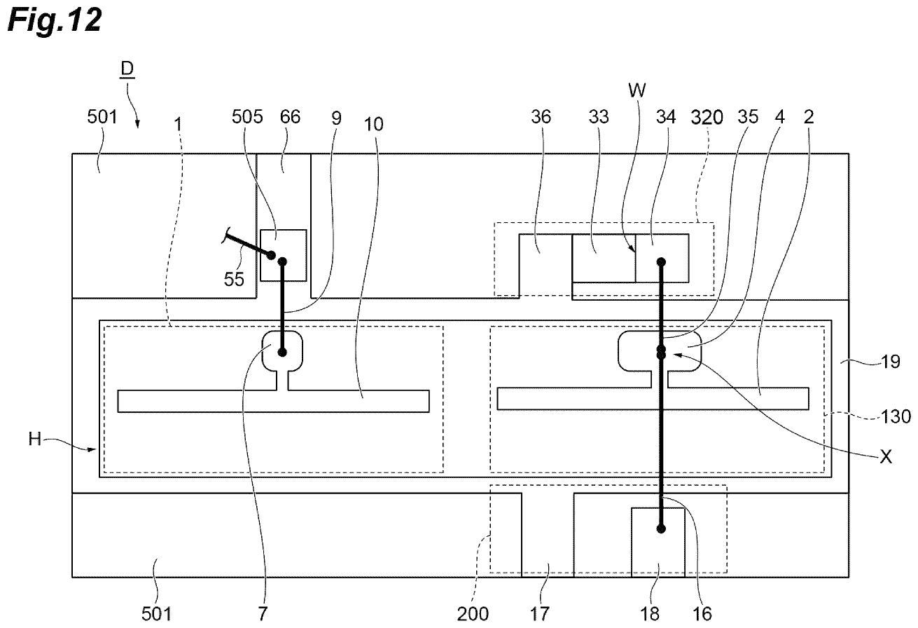

Advantageous effects obtained with the optical semiconductor device A having the aforementioned configuration will be described low. FIG. 12 is a plan view illustrating an optical semiconductor device D according to a comparative example. The optical semiconductor device D is different from the optical semiconductor device A in the following points. The optical semiconductor device D includes an optical modulator integrated semiconductor laser H instead of the optical modulator integrated semiconductor laser E and a terminating portion 320. The optical modulator integrated semiconductor laser H includes an optical modulation portion 130 instead of the optical modulation portion 100. The optical modulation portion 130 is disposed on a side of a lens (not illustrated) with respect to the laser portion 1. The pad 3, the wires 15 and 24, and the terminating portion 300 are not provided in the optical modulation portion 130. The terminating portion 320 is provided on the substrate 501 on the side opposite to the transmission line 200 with respect to the optical modulation portion 130. In the terminating portion 320, wiring patterns 34 and 36 and a resistive film 33 are provided in the direction in which the laser portion 1 and the optical modulation portion 130 are arranged. The resistive film 33 is disposed to be interposed between the wiring patterns 34 and 36. The wiring pattern 34 is connected to the pad 4 via a wire 35. The wiring pattern 36 is in contact with the ground pattern 19. In the optical semiconductor device D, since the terminating portion 320 is provided outside of the optical modulator integrated semiconductor laser H, the length of the transmission line from one end W of the resistive film 33 of the terminating portion 320 to a connection point X between the wire 16 and the pad 4 is longer. In this case, since mismatching in impedance is increased, electrical reflection of a modulation signal in the resistive film 33 is likely to increase with an increase in frequency band of the optical modulator integrated semiconductor laser. On the other hand, in the optical semiconductor device A, the pad 3, the pad 4, and the resistive film 31 that is included in the terminating portion 300 are provided on the same substrate 6. Accordingly, a length L1 of a conductive path between one end Y of the resistive film 31 and the connection point X between the wire 16 and the pad 4 can be decreased. As a result, in the optical semiconductor device A, electrical reflection of the modulation signal in the resistive film 31 of the terminating portion 300 is less likely to increase. Accordingly, it is possible to obtain an optical modulator integrated semiconductor laser E that can decrease a loss of a modulation signal.

In the optical semiconductor device A, the pad 3 is connected to the ground potential line 17 via the wire 15. Accordingly, the wire 15 having the ground potential can be provided on the optical modulator integrated semiconductor laser E. The signal line 18 is connected to the wire 16. The ground potential line 17 is connected to the wire 15. Accordingly, the wire 15 and the wire 16 are arranged side by side with each other. As a result, the modulation signal propagates side by side with the ground potential even after the modulation signal has left the signal line 18. Accordingly, it is possible to decrease mismatching in impedance between the signal line 18 and the wire 16. As a result, it is possible to decrease a loss of the modulation signal due to mismatching in impedance of the modulation signal.

In this embodiment, the length L1 of the conductive path between one end Y of the resistive film 31 and the connection point X between the wire 16 and the pad 4 may be less than ¼ of a wavelength of the modulation signal. According to the inventor's knowledge, even if an input modulation signal has a high frequency such as 100 GHz or higher, it is less likely to increase electrical reflection of the modulation signal from one end Y of the resistive film 31 when the length of the conductive path between one end Y of the resistive film 31 and the connection point X between the wire 16 and the pad 4 is less than ¼ of a wavelength of the modulation signal. Accordingly, it is possible to effectively decrease a loss of the modulation signal due to reflection. In 100 Gbps communication, it is preferable that the value of ¼ of the wavelength of the modulation signal be, for example, 300 μm, and the length L1 be, for example, equal to or less than 100 μm.

In the optical semiconductor device A according to this embodiment, the resistive film 31 may include at least one material included in a group consisting of nickel chromium, titanium tungsten, tantalum nitride, and platinum. Accordingly, close adhesion between the resistive film 31 and the passivation film 101 is improved. It is possible to obtain a desired resistance value.

In the optical semiconductor device A according to this embodiment, the wire 15 and the wire 16 may be provided in parallel with each other. Since the wire 15 and the wire 16 are provided in parallel with each other, it is possible to further decrease mismatching in impedance between the signal line 18 and the wire 16. Accordingly, it is possible to further decrease a loss of a modulation signal due to mismatching in impedance.

The optical semiconductor device A according to this embodiment may further include the ground pattern 19 provided on the side opposite to the transmission line 200 with respect to the optical modulation portion 100. The ground pattern 19 and the pad 3 may be connected to each other via the wire 24. With the wire 24, it is possible to enhance precision of the ground potential of the pad 4 and to further decrease the mismatching in impedance between the signal line 18 and the wire 16. Accordingly, it is possible to further decrease the loss of the modulation signal due to the mismatching in impedance.

The laser portion 1 outputting the laser light may be provided on the substrate 6. Accordingly, the laser portion 1 and the optical modulation portion 100 can be monolithically provided on the same substrate 6 and can decrease a size of the small optical transmission device A1.

The optical modulator integrated semiconductor laser E according to this embodiment includes the substrate 6, the optical modulation portion 100 provided on the substrate 6 and modulating laser light, the optical modulation portion 100 including the modulation electrode 2 that is supplied with a modulation signal, and the terminating portion 300 provided on the substrate 6 and connected to the modulation electrode 2 and a conductor having the ground potential, the terminating portion 300 including the resistive film 31. By disposing the optical modulation portion 100 and the terminating portion 300 that includes the resistive film 31 on the same substrate 6, it is possible to decrease a distance between the modulation electrode 2 of the optical modulation portion 100 and the terminating portion 300. Accordingly, it is possible to decrease electrical reflection of the modulation signal from the resistive film 31. As a result, it is possible to obtain an optical modulator integrated semiconductor laser E that can decrease a loss of the modulation signal due to reflection.

### First Modified Example

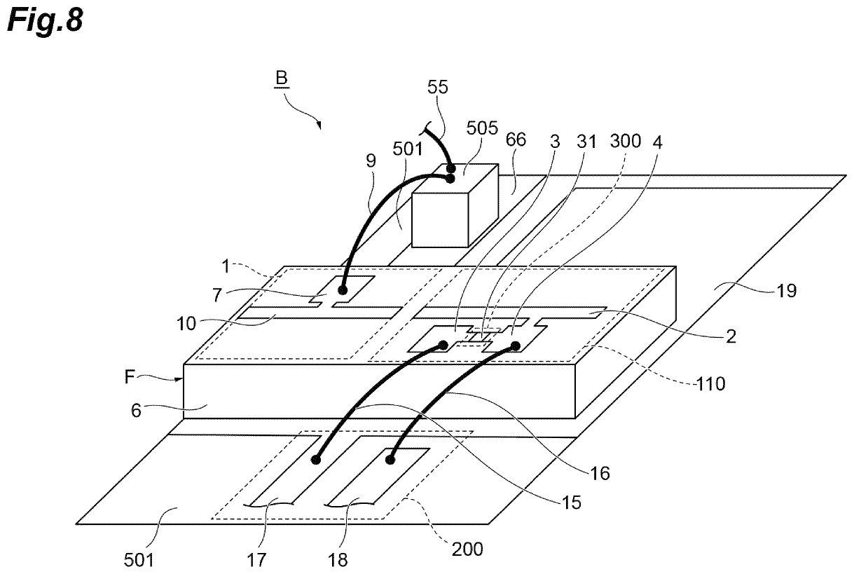

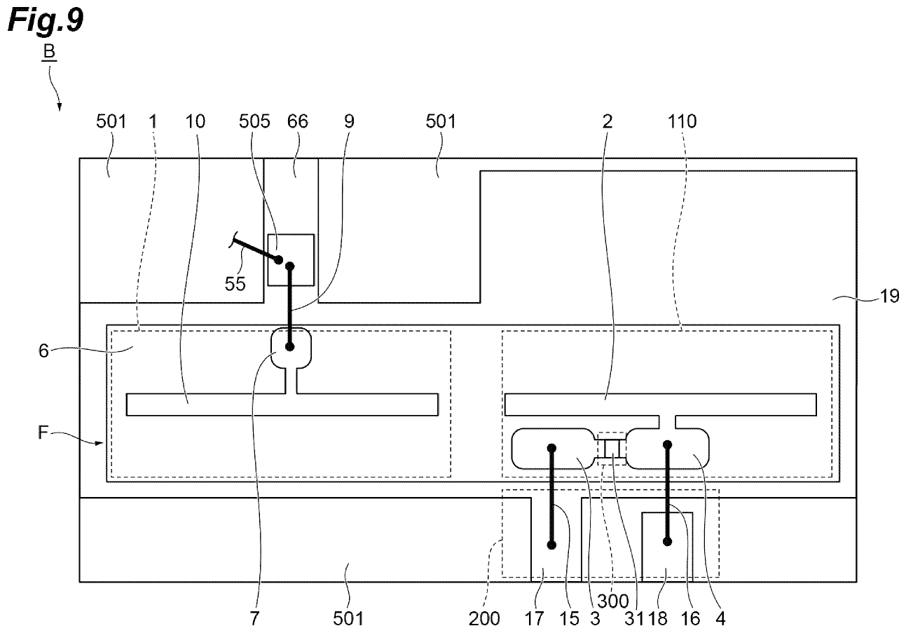

FIG. 8 is a perspective view illustrating an optical semiconductor device B according to a first modified example. FIG. 9 is a plan view illustrating the optical semiconductor device B. The optical semiconductor device B is different from the optical semiconductor device A in the following points, and they are the same in the other points. The optical semiconductor device B includes an optical modulator integrated semiconductor laser F instead of the optical modulator integrated semiconductor laser E. The optical modulator integrated semiconductor laser F includes an optical modulation portion 110 instead of the optical modulation portion 100. The other configuration of the optical modulator integrated semiconductor laser F is the same as that of the optical modulator integrated semiconductor laser E. In the optical modulation portion 110, the pads 3 and 4 and the terminating portion 300 are provided on the side of the transmission line 200 with respect to the modulation electrode 2, and the wire 24 (see FIGS. 3 and 4) is not provided.

In the optical semiconductor device B having the aforementioned configuration, the same advantageous effects as in the optical semiconductor device A are obtained. Since the pads 3 and 4 are provided on the side of the transmission line 200 with respect to the modulation electrode 2, it is possible to decrease the lengths of the wires 15 and 16.

### Second Embodiment

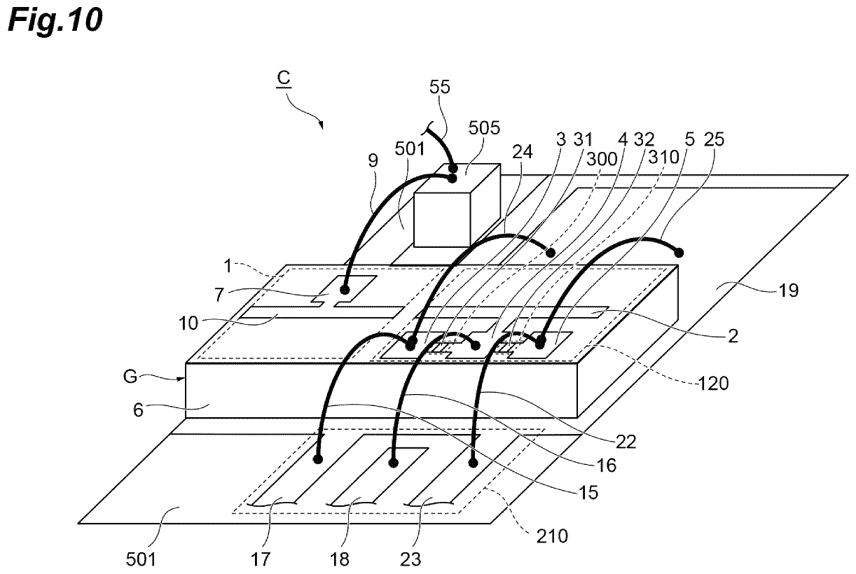

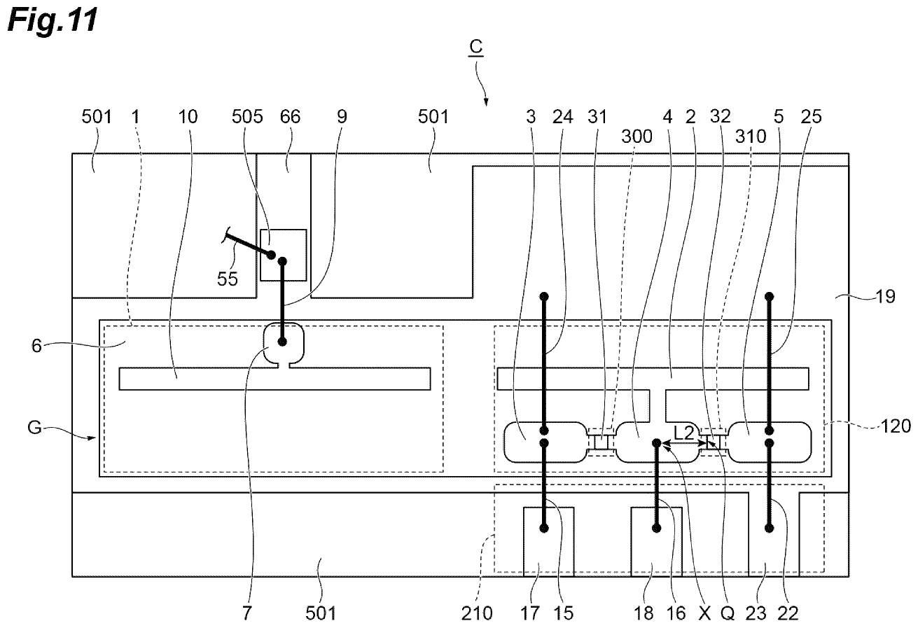

FIG. 10 is a perspective view illustrating an optical semiconductor device C according to a second embodiment. FIG. 11 is a plan view illustrating the optical semiconductor device C. The optical semiconductor device C is different from the optical semiconductor device B in the following points, and they are the same in the other points. The optical semiconductor device C includes an optical modulator integrated semiconductor laser G instead of the optical modulator integrated semiconductor laser F and includes a transmission line 210 instead of the transmission line 200. The optical modulator integrated semiconductor laser G includes an optical modulation portion 120 instead of the optical modulation portion 100. The other configuration of the optical modulator integrated semiconductor laser G is the same as that of the optical modulator integrated semiconductor laser F.

The optical modulator integrated semiconductor laser G includes a terminating portion 310 (a second terminating portion) in addition to the terminating portion 300, and the optical modulation portion 120 includes a pad 5 (a second pad) in addition to the pads 3 and 4. The pad 5 is provided on the substrate 6 opposite to the pad 3 with respect to the pad 4 and is connected to a wire 22 (a third wire) having the ground potential. The pad 5 is formed in a film shape and has a substantially rectangular shape in a plan view. The material of the pad 5 is a metal, for example, gold (Au). The thickness of the pad 5 is, for example, equal to or greater than 3 μm and equal to or less than 10 μm.

The terminating portion 310 includes a resistive film 32 (a second resistive film) and decreases reflection of a modulation signal. The terminating portion 310 is provided on the substrate 6. One end of the resistive film 32 is connected to the pad 4 via a wiring pattern. The other end of the resistive film 32 is connected to the pad 5 via a wiring pattern. A length of a conductive path (an electrical length) L2 between a connection point X between the wire 16 and the pad 4 and the one end Q of the resistive film 32 is less than ¼, less than ⅛, less than 1/10, or less than 1/12 of a wavelength of a modulation signal and equal to or greater than 1/1000 of the wavelength. In a specific example, when the wavelength of the modulation signal is, for example, 1200 μm, L2 is less than 300 μm, less than 150 μm, less than 120 μm, or less than 100 μm and equal to or greater than 1 μm. The resistive film 32 has a rectangular shape. The material of the resistive film 32 is, for example, a metal such as nickel chromium (NiCr), titanium tungsten (TiW), tantalum nitride (TaN), or platinum (Pt). The thickness of the resistive film 32 is, for example, equal to or greater than 100 nm and equal to or less than 300 nm. The resistive film 32 is formed through vapor deposition, lifting-off, sputtering, or the like. When an impedance value of a light absorbing layer is, for example, 90Ω, a value of terminating impedance is 50Ω by setting the resistance value of the resistive film 32 to, for example, 220Ω. The value of terminating impedance is often set to 50Ω, or may be different from 50Ω due to addition of a capacitor or an inductor or adjustment of a resistance value.

The transmission line 210 includes the signal line 18, the ground potential line 17, and the ground potential line 23 (a second ground potential line). The ground potential line 23 is connected to the pad 5 via the wire 22. The signal line 18 transmits a modulation signal, and the ground potential line 17 and the ground potential line 23 have the ground potential.

The ground pattern 19 and the pad 5 are connected to each other via a wire 25 (a fifth wire). The wire 22 is provided on the side opposite to the wire 15 with respect to the wire 16. The wire 22 and the wire 25 are, for example, bonding wires formed of Au. A sectional diameter of the wire 22 and the wire 25 is, for example, 25 μm.

In the optical semiconductor device C having the aforementioned configuration, when the pad 5 and the ground potential line 23 are connected to each other via the wire 22, the wire 22 has the ground potential. Accordingly, the wire 16 disposed along with the wire 15 and the wire 22 is interposed between the ground potentials. As a result, the modulation signal passing along the wire 16 propagates while being interposed between the ground potentials. Accordingly, it is possible to further decrease mismatching in impedance between the signal line 18 and the wire 16. As a result, it is possible to further decrease a loss of the modulation signal due to mismatching in impedance. The pad 4, the pad 5, and the resistive film 32 are provided on the same substrate 6. Accordingly, the length L2 of the conductive path between the connection point X between the wire 16 and the pad 4 and one end Q of the resistive film 32 can be extremely decreased. As a result, it is possible to decrease electrical reflection of the modulation signal from one end Q of the resistive film 32. Accordingly, it is possible to obtain an optical modulator that can further decrease a loss of a modulation signal due to reflection.

In this embodiment, the length L2 of the conductive path between the connection point X between the wire 16 and the pad 4 and one end Q of the resistive film 32 may be less than ¼ of a wavelength of the modulation signal. Accordingly, it is possible to effectively decrease a loss of the modulation signal due to reflection from one end Q of the resistive film 32.

The optical semiconductor device C according to this embodiment may further include the ground pattern 19 provided on the side opposite to the transmission line 200 with respect to the optical modulation portion 120. The ground pattern 19 and the pad 3 may be connected to each other via a wire 24. The ground pattern 19 and the pad 5 may be connected to each other via the wire 25. With the wire 24 and the wire 25, it is possible to enhance precision of the ground potential of the pad 3 and the pad 5 and to further decrease the mismatching in impedance between the signal line 18 and the wire 16. Accordingly, it is possible to further decrease the loss of the modulation signal due to the mismatching in impedance.

The optical modulator integrated semiconductor laser, the optical modulator, and the optical semiconductor device according to the present disclosure are not limited to the aforementioned embodiments and the aforementioned modified examples and can be modified in various other forms. For example, the wire 15 and the wire 16 are parallel with each other in the aforementioned embodiments, but the wire 15 and the wire 16 may be oblique each other. Similarly, the wire 22 and the wire 16 may be oblique each other in the first modified example. In this case, by disposing the wire 15 and the wire 16 side by side (or such that the wire 16 is interposed between the wire 15 and the wire 22), it is possible to obtain the aforementioned advantageous effects.

In the aforementioned embodiments, the ground potential line 17 of the transmission line 200 is provided on the substrate 502 along with the signal line 18, but the transmission line is not limited to this example. For example, even when the transmission line is formed as a so-called micro strip line in which the ground potential line is provided on the rear surface of the substrate 501, it is possible to obtain the aforementioned advantageous effects.

What is claimed is:

1. An optical modulator integrated laser comprising:
a substrate;
a laser portion provided on the substrate and outputting laser light;
an optical modulation portion provided on the substrate and modulating the laser light; and
a first terminating portion provided on the substrate and including a first resistive film,
wherein the optical modulation portion includes
a modulation electrode that is supplied with a modulation signal,
a signal pad connected to the modulation electrode and for being connected to a first wire for inputting the modulation signal to the optical modulation portion, and
a first pad for being connected to a second wire having a ground potential,
wherein the signal pad and one end of the first resistive film are connected to each other, and
wherein another end of the first resistive film and the first pad are connected to each other.

2. The optical modulator integrated laser according to claim 1, wherein a length of a conductive path between the one end of the first resistive film and a connection point between the first wire and the signal pad is less than ¼ of a wavelength of the modulation signal.

3. The optical modulator integrated laser according to claim 1, further comprising a second terminating portion provided on the substrate and including a second resistive film,
wherein the optical modulation portion further includes a second pad provided on a side opposite to the first pad with respect to the signal pad and for being connected to a third wire having the ground potential,
wherein the signal pad and one end of the second resistive film are connected to each other, and
wherein another end of the second resistive film and the second pad are connected to each other.

4. The optical modulator integrated laser according to claim 3, wherein a length of a conductive path between the one end of the second resistive film and a connection point between the first wire and the signal pad is less than ¼ of a wavelength of the modulation signal.

5. An optical modulator comprising:
a substrate;
an optical modulation portion provided on the substrate and modulating laser light; and
a first terminating portion provided on the substrate and including a first resistive film,
wherein the optical modulation portion includes
a modulation electrode that is supplied with a modulation signal,
a signal pad connected to the modulation electrode and for being connected to a first wire for inputting the modulation signal to the optical modulation portion, and
a first pad for being connected to a second wire having a ground potential,
wherein the signal pad and one end of the first resistive film are connected to each other, and
wherein another end of the first resistive film and the first pad are connected to each other.

6. The optical modulator according to claim 5, wherein a length of a conductive path between the one end of the first resistive film and a connection point between the first wire and the signal pad is less than ¼ of a wavelength of the modulation signal.

7. The optical modulator according to claim 5, further comprising a second terminating portion provided on the substrate and including a second resistive film,
wherein the optical modulation portion further includes a second pad provided on a side opposite to the first pad with respect to the signal pad and for being connected to a third wire having the ground potential,
wherein the signal pad and one end of the second resistive film are connected to each other, and
wherein another end of the second resistive film and the second pad are connected to each other.

8. The optical modulator according to claim 7, wherein a length of a conductive path between the one end of the second resistive film and a connection point between the first wire and the signal pad is less than ¼ of a wavelength of the modulation signal.

9. The optical modulator according to claim 5, further comprising a laser portion provided on the substrate and outputting the laser light.

10. An optical semiconductor device comprising:
the optical modulator according to claim 5; and
a transmission line transmitting the modulation signal,
wherein the transmission line includes
a signal line transmitting the modulation signal, and
a first ground potential line having the ground potential and provided in parallel with the signal line,
wherein the signal pad and the signal line are connected to each other via the first wire, and
wherein the first pad and the first ground potential line are connected to each other via the second wire.

11. The optical semiconductor device according to claim 10, further comprising a ground pattern provided on a side opposite to the transmission line with respect to the optical modulation portion,
wherein the ground pattern and the first pad are connected to each other via a fourth wire.

12. An optical semiconductor device comprising:
the optical modulator according to claim 7; and
a transmission line transmitting the modulation signal,
wherein the transmission line includes
a signal line transmitting the modulation signal, and
a first ground potential line and a second ground potential line having the ground potential and provided side by side with the signal line,
wherein the signal pad and the signal line are connected to each other via the first wire,
wherein the first pad and the first ground potential line are connected to each other via the second wire,
wherein the second pad and the second ground potential line are connected to each other via the third wire, and
wherein the third wire is provided on a side opposite to the second wire with respect to the first wire.

13. The optical semiconductor device according to claim 12, further comprising a ground pattern provided on a side opposite to the transmission line with respect to the optical modulation portion,
wherein the ground pattern and the first pad are connected to each other via a fourth wire, and
wherein the ground pattern and the second pad are connected to each other via a fifth wire.

14. An optical modulator comprising:
a substrate;
an optical modulation portion provided on the substrate, and modulating laser light, the optical modulation portion including a modulation electrode that is supplied with a modulation signal; and
a terminating portion provided on the substrate and connected to the modulation electrode and a conductor having a ground potential, the terminating portion including a resistive film.
